(19) United States
(12) Patent Application Publication
(10) Pub. No.: US 2010/0089624 A1
(43) Pub. Date: Apr. 15, 2010

(54) MULTILAYER CERAMIC SUBSTRATE AND PROCESS FOR PRODUCING THE SAME

(76) Inventors: Hidekazu Tamai, Kyoto (JP); Nobuyuki Aoki, Osaka (JP); Satoshi Tomioka, Osaka (JP); Hiroshi Kagata, Osaka (JP)

Correspondence Address: MCDERMOTT WILL & EMERY LLP, 600 13TH STREET, NW, WASHINGTON, DC, 20005-3096, US

(21) Appl. No.: 12/523,813

(22) PCT Filed: Feb. 12, 2008
(86) PCT No.: PCT/JP2008/000198

§ 371 Date: Jul. 20, 2009

(30) Foreign Application Priority Data
Feb. 16, 2007 (JP) 2007-036081

(51) Int. Cl. H05K 1/09; C03B 29/00

(52) U.S. Cl. 174/257; 156/89.12

(57) ABSTRACT

Disclosed is a multi-layer ceramic substrate including a glass ceramic and an external terminal formed on a surface of the glass ceramic. The external terminal includes conductive materials mainly composed of at least one among Ag, Au, Pt and Pd, and added with at least one element among Bi, Cu, Ge, Mn, Ti and Zn. Inorganic oxide particles are provided on a surface of the external terminal. The multi-layer ceramic substrate can keep adhesive strength being unchanged after humidity test or after plating and can prevent plating sag and solder leach from occurring.

### TECHNICAL FIELD

The present invention relates to a multi-layer ceramic substrate with an external terminal and process for producing the same.

### BACKGROUND ART

Compact and composite electronic components are required to realize downsized and high-density electronic equipment, which advances developments of compact modular components or the like. A ceramic module component having a variety of electronic components mounted on the top layer of a multi-layer ceramic substrate has come into practical use as a way to realize the need. A flat and dimensionally accurate multi-layer ceramic component is required in recent years, and therefore most producing methods of the multi-layer ceramic substrate have used a shrink-proof layer to meet the accuracy. A typical producing method is described below.

To produce the multi-layer ceramic substrate, ceramic slurry is prepared first by mixing and dispersing organic solvent such as organic binder and plasticizer into a filler including glass materials. The ceramic slurry is coated on a base-film composed of PET by doctor blade method, die-coating method or the like to form a ceramic green sheet. Conductive patterns are formed on the ceramic green sheet by using a conductive paste. If necessary, via-holes having been formed beforehand on the ceramic green sheets by punching or laser machining are filled with the conductive paste to form conductive via-holes.

Next, a layered-green-sheet is produced by thermo-compression through heating and pressurizing the ceramic green sheets repeatedly. Now, another ceramic green sheet formed from an inorganic compound that is not sintered at the firing temperature of the ceramic green sheet is layered on at least one surface of the layered-green-sheet as a shrink-proof layer before firing the layered-green-sheet. The shrink-proof layer can control shrinking in planar direction greatly, and the ceramic green sheet shrinks selectively in thickness direction only. This makes it possible to produce a flat and dimensionally accurate multi-layer ceramic substrate.

The external terminal having glass additives has been typically used for conventional multi-layer ceramic substrates. A conductive paste, formed from conductive powder and glass frit turned into paste state in an organic binder, is coated and dried on a substrate using screen printing method or the like before firing it to form a typical external terminal.

In case of firing a layered-green-sheet provided with the shrink-proof layer, using a conductive paste with a limited composition and amount of additives to the glass frit for the external terminal enables the multi-layer ceramic substrate and external terminal to be co-fired. This can prevent the external terminal from peeling off in blast finishing, and has been well known as a producing method keeping productivity of the external terminal unchanged while the quality is maintained. Following patent document 1 is known as an example of a prior art document concerning the present invention.

In the conventional producing method, however, the external terminal is printed and fired on the substrate following blast finishing of the sintered substrate, which causes a drawback of increase in producing steps and poor productivity causing cost increase. Producing method of patent document 1 describes that the external terminal can be co-fired by glass additives into the external terminal to improve adhesive strength with the substrate, but plating sags would tend to occur even if the adhesive with the substrate alone may be strengthened. Moreover, the external terminal is not likely sintered densely enough by just adding glass to the external terminal, and plating solution or moisture would tend to come into the substrate, causing the adhesive strength to weaken after humidity test or after plating.

[Patent document 1] Japanese Patent Publication No. 3826685.

### DISCLOSURE OF THE INVENTION

The present invention provides a multi-layer ceramic substrate that can be co-fired with external terminal and can prevent plating sag from occurring, and allows less plating solution or moisture to come into the substrate due to the densely sintered external terminal. The multi-layer ceramic substrate of the present invention includes a glass ceramic and an external terminal formed on one of the surfaces of the glass ceramic: the external terminal shall be a conductive material including mainly at least one among Ag (silver), Au (gold), Pt (platinum) and Pd (palladium), and includes at least one element among Bi (bismuth), Cu (copper), Ge (germanium), Mn (manganese), Ti (titanium) and Zn (zinc) additionally; and is provided with inorganic oxide particles on its surface. The following is described using atomic symbols only.

Including at least one element among Bi, Cu, Ge, Mn, Ti and Zn can sinter the external terminal densely, which can keep the adhesive strength unchanged after humidity test or after plating with little infiltration of plating solution or moisture. Moreover, inorganic oxide particles provided on a surface of the external terminal could prevent plating sag and solder leach from occurring. The inorganic oxide particle shall include at least one among Al₂O₃, ZrO₂ and MgO as the main material. This can prevent the plating sag and solder leach from occurring more effectively.

### BRIEF DESCRIPTION OF THE DRAWINGS

FIG. 1 shows a cross-sectional view of a layered body in accordance with an exemplary embodiment of the present invention.

FIG. 2 shows a cross-sectional view of the multi-layer ceramic substrate in accordance with the exemplary embodiment of the present invention.

FIG. 3 shows a schematic cross-sectional view of the multi-layer ceramic substrate in accordance with the exemplary embodiment of the present invention.

### REFERENCE MARKS IN THE DRAWINGS

1. shrink-proof layer
2. layered-green-sheet
2a. glass ceramic
3. lamination
4. external terminal
5. multi-layer ceramic substrate
6. inorganic oxide particle
7. topside layer
8. inside layer

### DETAILED DESCRIPTION OF PREFERRED EMBODIMENTS

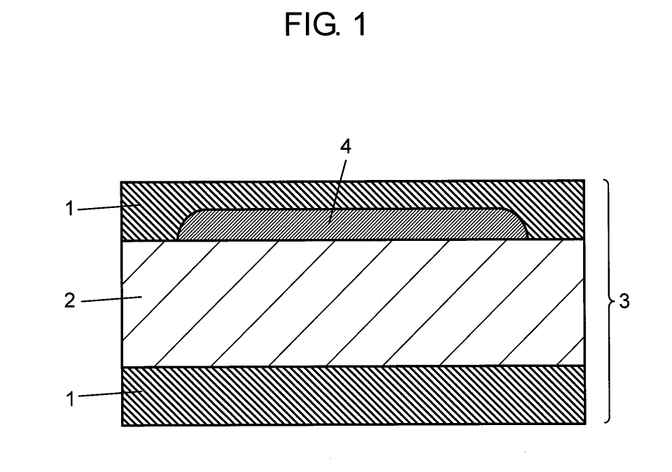

Now, the multi-layer ceramic substrate of the present invention is described with reference to the drawings. FIG. 1 shows a cross-sectional view of a lamination in accordance with an exemplary embodiment of the present invention. The cross-sectional view shows an intermediate step of the producing process. In FIG. 1, non-sintered external terminal 4 is formed on layered-green-sheet 2. Layered-green-sheets 2 and non-sintered external terminal 4 are formed sandwiched between shrink-proof layers 1. Following is the producing method for such a multi-layer ceramic substrate of the present invention.

Glass material shall be alkaline earth silicate series glass including 40 to 50 wt % of SiO₂, 0 to 10 wt % of B₂O₃ and 25 to 50 wt % of MO (M is at least more than one elements among Ba, Ca and Sr). Filler shall include at least Al₂O₃, MgO and ROa (R is an element selected at least one among La, Ce, Pr, Nd, Sm and Gd, and a is a value determined stoichiometrically according to the valence of R). The glass has an effect on the external terminal 4 added with an element among Bi, Cu, Ge, Mn, Ti or Zn to sinter more densely, and since glass ceramic is sintered at the temperature not higher than 900° C. Ag can be the main material for the external terminal 4, enabling the glass ceramic substrate to use for high frequency application.

The glass and filler described above are mixed and dispersed in an organic solvent such as organic binder and plasticizer to prepare a ceramic slurry. The ceramic slurry is coated on a base-film composed of PET by doctor blade method, die-coating method or the like to form a ceramic green sheet. Although the glass and the filler are adopted in the exemplary embodiment of the present invention, the glass and the filler are not limited to these only but any material is available if the material can be co-fired with a conductive compound.

Next, the ceramic green sheets are heated and pressurized repeatedly for thermo-compression bonding to form layered-green-sheet 2. External terminal 4 to mount a variety of electronic components or to be mounted on a multi-layer ceramic substrate is formed by printing on the topside layer of the layered body. Conductive paste to form the external terminal 4 adopts metal Ag in the exemplary embodiment, but Ag alloys such as Ag—Pd, Ag—Pt and Ag—Rh can be the alternatives. Sometimes, alumina or inorganic compound such as glass can be added to the conductive paste if the extent meets the property.

Next, shrink-proof layers 1 composed mainly of Al₂O₃ are layered on the top and bottom surfaces of layered-green-sheet 2 to form lamination 3. Although Al₂O₃ is used as a sintering resistant inorganic material for shrink-proof layer 1 in the exemplary embodiment, similar effects can be expected from MgO, ZrO₂ or the like.

After removing organic binder, lamination 3 is burned at the temperature at which layered-green-sheet 2 is sintered but shrink-proof layer 1 is not, and then shrink-proof layer 1 is removed from lamination 3.

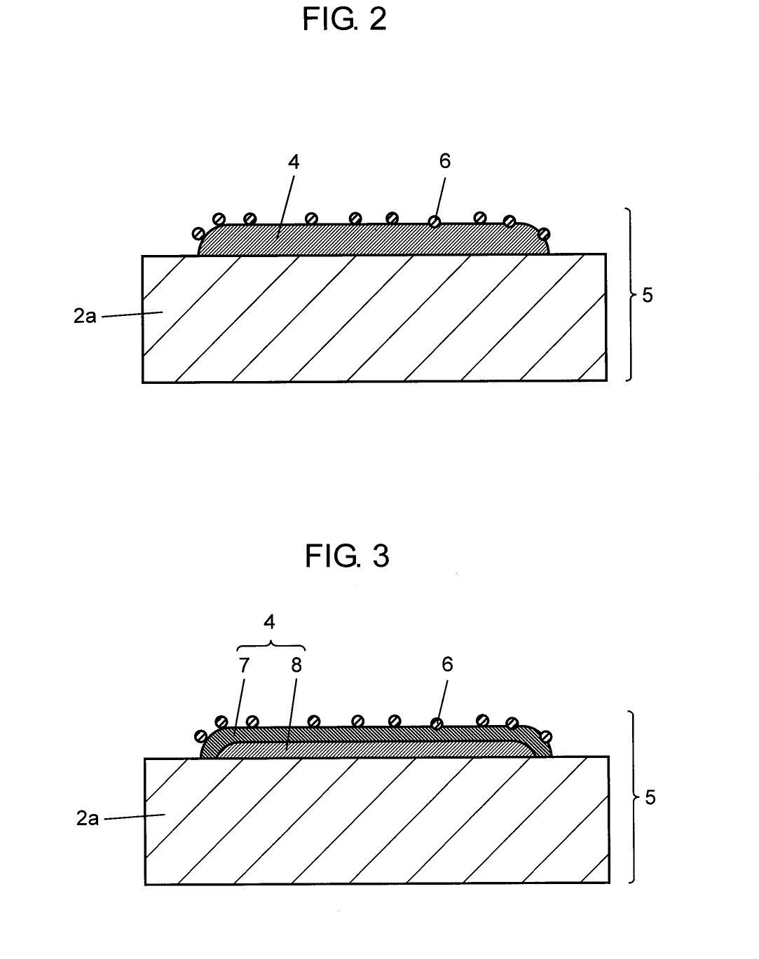

FIG. 2 shows a cross-sectional view of the multi-layer ceramic substrate 5 of the exemplary embodiment. Sintered external terminal 4 is formed on glass ceramic 2a. Inorganic oxide particles 6 are provided on the surface of the external terminal 4. Inorganic oxide particles 6 are provided not covering entire surface of external terminal 4. They scatter sparsely on external terminal 4. Covering the entire surface of external terminal 4, inorganic oxide particles 6 would cause a failure in plating later. If all of inorganic oxide particles 6 are fully removed, the properties would become poor as described later. To build this configuration, shrink-proof layer 1 formed from the sintering resistant inorganic material is not fully but partially removed from the surface of the external terminal 4 to use the residual as inorganic oxide particles 6. Though shrink-proof layer 1 is removed by spraying blast method of slurried Al₂O3 media in the exemplary embodiment, a similar effect can be expected through spraying blast of non-slurried media. Other methods such as ultrasonic cleaning, brush cleaning or the like may also be available. Al₂O₃ is used as a media in the exemplary embodiment but a similar effect can be expected by using ZrO₂, ZrO₂ nitrides, SiC or the like.

How to evaluate is described next.

Density level of the external terminal 4 is evaluated from vacancy area ratios measured using SEM (scanning electron microscope) in the cross-section of the external terminal 4 on multi-layer ceramic substrate exposed by CP (cross-sectional polishing). If the area ratio is less than 7%, it is evaluated as “OK”, and not lower than 7% as “NG” respectively.

Humidity test is proceeded such that a ceramic substrate provided with a terminal of 2 mm square is stored in a thermostatic chamber at 85° C. and 85% R.H. for 1000 hours, then a jig is soldered on the terminal, and the terminal is peeled off using a tension tester to determine the strength needed for the peeling as the adhesive strength. If the adhesive strength after the humidity test remains not smaller than 50 N/2 mm-square, it is evaluated as “OK”, and less than the value as “NG” respectively. The measuring sample size is 25 pieces each to calculate the average value.

Resistance of plating is evaluated by a method similar to humidity test, if the adhesive strength after plating remains not smaller than 50 N/2 mm-square, it is evaluated as “OK”, and less than the value as “NG” respectively. The measuring sample size is 25 pieces each to calculate the average value.

Plating sag is evaluated by presence or absence of short circuit reject after plating using a wiring pattern of L/S=30 μm/30 μm. The measuring sample size is 50 pieces each and if there is even only one reject in 50 pieces, the sample is evaluated as “NG”.

Solder leach is evaluated such that the samples are first immersed in a flux, then immersed in a melted Sn/3Ag/0.5Cu solder bath at 270° C. for 10 sec. and residual ratio of the external terminal 4 is measured for the evaluation. Specifically, when dissolution is observed little in the external terminal 4 and the residual ratio is not smaller than 80%, it is evaluated as “OK”, and when is than 80% it is evaluated as “NG”. The sample size is 20 pieces each to calculate the average value.

### Exemplary Embodiment 1

The evaluation results of exemplary embodiment 1 of the present invention are described below. First, external terminals 4 of the samples are each added with one element among Bi, Cu, Ge, Mn, Ti and Zn respectively. With a spraying condition of slurried Al₂O₃ applied for each sample, the substrates are produced to evaluate in two groups: samples having external terminal 4 provided with inorganic oxide particles 6 on its surface (“with”); and samples having external terminal 4 in which all of the inorganic oxide particles 6 are removed fully from its surface (“without”).

Each element is added as an oxide compound such as Bi₂O₃, CuO, GeO₂, MnO, TiO₂ and ZnO respectively, doping each 2 pts.wt. for 100 pts.wt. of Ag. The results are shown in table 1.

(Table 1)

Table 1 shows good results in every evaluation item for samples no.1 to 6 of the present invention. In contrast, sample no. 7 formed from Ag only without any additional element, shown as a control example, doesn't show good results in all evaluation items of density level, humidity test, plating, plating sag and solder leach. Sample no. 8 provided with inorganic oxide particles 6 on the surface of external terminal 4 shows good results in plating sag and solder leach. That is, inorganic oxide particles 6 provided on the sample can prevent plating sag and solder leach from occurring. Sample no. 9 to 14 each added with an additive element can show good evaluation results on density level, adhesive strength after humidity test and adhesive strength after plating. Adding at least one element among Bi, Cu, Ge, Mn, Ti and Zn can improve the density of the external terminal 4 and can give good results in adhesive strength after humidity test and after plating consequently.

As described above, adding at least one element among Bi, Cu, Ge, Mn, Ti and Zn can improve the density of the external terminal 4 and forming at least inorganic oxide particles 6 on the surface of external terminal 4 can improve the density of external terminal 4 and adhesive strength after humidity test and after plating and can realize effects to prevent plating sag or solder leach from occurring.

### Exemplary Embodiment 2

First, external terminals 4 of the samples are each added with one among Bi, Cu, Ge, Mn, Ti and Zn, in addition to the glass used for glass ceramic 2a. With a spraying condition of wet-blast for each sample, the substrates are produced to evaluate in two sample groups: samples of external terminal 4 provided with inorganic oxide particles 6 on its surface (“with”); and samples in which all of inorganic oxide particles 6 are removed from its surface (“without”). Each element is added as an oxide compound such as Bi₂O₃, CuO, GeO₂, MnO, TiO₂ and ZnO respectively, doping each 1 pts.wt. for 100 pts.wt. of Ag. The results are shown in table 2.

(Table 2)

Table 2 shows good results in every evaluation item for samples no. 15 to 20 of exemplary embodiment 2 of the present invention. It is observed that the adhesive strength after humidity test and after plating are improved respectively and that adding of glass can increase the bonding strength to glass ceramic 2a. In contrast, an increase in adhesive strength after plating is observed in control examples no. 21 and 22, but no good results in other evaluation items. Comparing with samples no. 1 to 6, samples no. 15 to 20 show slightly better evaluation results.

From the above, adding glass into the external terminal 4 can improve adhesive strength after humidity test and after plating effectively.

### Exemplary Embodiment 3

First, external terminals 4 of the samples are each added with 2 pts.wt. of oxide compounds such as Bi₂O₃, CuO, GeO₂, MnO, TiO₂ or ZnO for 100 pts.wt. of Ag respectively; and in addition to this, the shrink-proof layer mainly composed of Al₂O₃, a sintering resistant inorganic material, is added with 1 pts.wt. of additive similar to that for external terminal 4 for 100 pts.wt. of Al₂O₃. The evaluation results are shown in table 3.

(Table 3)

Table 3 shows good results in every evaluation item for samples no. 23 to 28 of the exemplary embodiment. The adhesive strength after humidity test and after plating show generally an improved tendency. This is considered that at least one element among Bi, Cu, Ge, Mn, Ti and Zn added into shrink-proof layer 1 can prevent the above elements also included in external terminal 4 from diffusing into shrink-proof layer 1 in the producing process of sintering layered-green-sheet 2 at the predetermined temperature to form the multi-layer ceramic substrate. It is also considered that external terminal 4 changes to a condition where the above elements are easy to move to the surface.

FIG. 3 shows a schematic cross-sectional view of the multi-layer ceramic substrate of the exemplary embodiment. Sintered external terminal 4 is formed on sintered glass ceramic 2a. External terminal 4 includes inside layer 8 and topside layer 7. Inorganic oxide particles 6 are provided on the surface of topside layer 7. The inorganic oxide particles are provided not covering the entire surface. They scatter sparsely on external terminal 4. The border between inside layer 8 and topside layer 7 is not clear practically. The cross-sectional view shows the fact schematically that density level changes from the surface to the inside gradually for an easy understanding. Topside layer 7 is sintered more densely than the inside, which can allow lesser plating solution or moisture to come into external terminal 4. That is, the adhesive strength after humidity test or after plating can be kept better.

Sample no. 29 and 30, shown as control examples, which have no additives to external terminal 4 and are added with Cu to shrink-proof layer 1, don't show sufficient density level for inside layer 8 of external terminal 4. However, it is observed that external terminal 4 is sintered densely near the topside. It is considered that the additives into the shrink-proof layer can improve the density of the topside layer of the external electrode. It is observed that the adhesive strength after humidity test or after plating is also improved, and also good results are obtained on plating sag and solder leach.

From the above results, shrink-proof layer 1 might include at least one element among Bi, Cu, Ge, Mn, Ti and Zn. It is considered that this prevents the additives of at least one element among Bi, Cu, Ge, Mn, Ti and Zn included in external terminal 4 from diffusing into shrink-proof layer 1 in the sintering process of layered-green-sheet 2 at the predetermined temperature to produce multi-layer ceramic substrate 5. The surface of external terminal 4 is considered to be in a condition for at least one element among Bi, Cu, Ge, Mn, Ti and Zn to be supplied easily, causing the surface of external terminal 4 to sinter more densely. This can keep the adhesive strength unchanged after humidity test or after plating with little infiltration of plating solution or moisture. Even if there is no additive on external terminal 4, considerable effects can be expected if an element is added to shrink-proof layer 1.

### Exemplary Embodiment 4

To investigate the blast effects of spraying slurry in the present invention, removing methods of shrink-proof layer 1 are tested. Samples whose shrink-proof layer 1 is removed by brushing are compared with those removed by spraying slurried Al₂O₃. The results are shown in table 4.

[Table 4]

The results compared with samples no. 1 to 6 whose shrink-proof layer 1 are removed by spraying slurried Al₂O₃ are described. Samples no. 31 to 36 having additives to external terminal 4 show good results in every evaluation item. It is observed, however, that samples no. 31 to 36 of exemplary embodiment 4 each corresponding to samples no. 1 to 6 of exemplary embodiment 1 respectively have weakened slightly in adhesive strength after humidity test or after plating. This is considered that the spraying of slurried Al₂O₃ can provide external terminal 4 with a denser surface and therefore can prevent plating solution or moisture from coming into, causing adhesive strength to improve.

According to the comparison results of samples no. 7 and 8 of exemplary embodiment 1 with samples no. 37 and 38 each corresponding to exemplary embodiment 4 respectively, samples whose shrink-proof layer 1 is removed by spraying slurried Al₂O₃ show a tendency of a higher adhesive strength after plating. This is also considered that the spraying of slurried Al₂O₃ can provide external terminal 4 with a denser surface and therefore can prevent plating solution or moisture from coming into, causing adhesive strength to improve.

### INDUSTRIAL APPLICABILITY

The present invention can provide a high quality multi-layer ceramic substrate with a densely sintered external terminal that can prevent plating solution or moisture from coming into, or can keep adhesive strength unchanged after humidity test or after plating and can prevent plating sag and solder leach from occurring.

TABLE 1

| | | | | | Adhesive strength | Adhesive strength | | |
|---|---|---|---|---|---|---|---|---|
| | | | Inorganic oxide | | after humidity test | after plating | | |
| | Sample no. | Added element | particle | Density | N/□2 mm | N/□2 mm | Plating sag | Solder leach |
| Exemplary | 1 | Bi | with | OK | OK 60 | OK 73 | OK | OK |
| embodiment | 2 | Cu | with | OK | OK 78 | OK 81 | OK | OK |
| | 3 | Ge | with | OK | OK 54 | OK 61 | OK | OK |
| | 4 | Mn | with | OK | OK 66 | OK 52 | OK | OK |
| | 5 | Ti | with | OK | OK 62 | OK 61 | OK | OK |
| | 6 | Zn | with | OK | OK 64 | OK 56 | OK | OK |
| Control | 7 | without | without | NG | NG 2 | NG 44 | NG | NG |
| example | 8 | without | with | NG | NG 2 | NG 36 | OK | OK |
| | 9 | Bi | without | OK | OK 52 | OK 64 | NG | OK |
| | 10 | Cu | without | OK | OK 73 | OK 76 | NG | NG |
| | 11 | Ge | without | OK | OK 58 | OK 66 | OK | NG |
| | 12 | Mn | without | OK | OK 67 | OK 50 | NG | OK |
| | 13 | Ti | without | OK | OK 51 | OK 52 | NG | NG |
| | 14 | Zn | without | OK | OK 67 | OK 64 | OK | NG |

TABLE 2

| | | | Inorganic | | | Adhesive strength | Adhesive strength | | |
|---|---|---|---|---|---|---|---|---|---|
| | | Added | oxide | Added | | after humidity test | after plating | Plating | Solder |
| | Sample no. | element | particle | glass | Density | N/□2 mm | N/□2 mm | sag | leach |
| Exemplary | 15 | Bi | with | with | OK | OK 67 | OK 78 | OK | OK |
| embodiment | 16 | Cu | with | with | OK | OK 86 | OK 82 | OK | OK |
| | 17 | Ge | with | with | OK | OK 55 | OK 68 | OK | OK |
| | 18 | Mn | with | with | OK | OK 71 | OK 58 | OK | OK |
| | 19 | Ti | with | with | OK | OK 70 | OK 72 | OK | OK |
| | 20 | Zn | with | with | OK | OK 67 | OK 59 | OK | OK |
| Control | 21 | without | without | with | NG | NG 2 | NG 51 | NG | NG |
| example | 22 | without | with | with | NG | NG 2 | NG 46 | OK | OK |

TABLE 3

| | | Added | | | | | Adhesive strength | | | |
|---|---|---|---|---|---|---|---|---|---|---|
| | | element | Inorganic | Added element | Density of | Density of | after | | | |
| | Sample | to external | oxide | to shrink-proof | terminal's | terminal's | humidity test | Adhesive strength | Plating | Solder |
| | no. | terminal | particle | layer | inside layer | topside layer | N/□2 mm | after plating | sag | leach |
| Exemplary | 23 | Bi | with | Bi | OK | OK | OK 72 | OK 87 | OK | OK |
| embodiment | 24 | Cu | with | Cu | OK | OK | OK 81 | OK 82 | OK | OK |
| | 25 | Ge | with | Ge | OK | OK | OK 58 | OK 73 | OK | OK |
| | 26 | Mn | with | Mn | OK | OK | OK 76 | OK 68 | OK | OK |
| | 27 | Ti | with | Ti | OK | OK | OK 78 | OK 80 | OK | OK |
| | 28 | Zn | with | Zn | OK | OK | OK 74 | OK 68 | OK | OK |
| Control | 29 | without | with- | Cu | NG | OK | NG 41 | NG 64 | OK | OK |
| example | | | out | | | | | | | |
| | 30 | without | with | Cu | NG | NG | NG 36 | NG 57 | OK | OK |

TABLE 4

| | | | Inorganic | Removing process | | Adhesive strength | Adhesive strength | | |
|---|---|---|---|---|---|---|---|---|---|
| | Sample | Added | oxide | of shrink-proof | | after humidity test | after plating | Plating | Solder |
| | no. | element | particle | layer | Density | N/□2 mm | N/□2 mm | sag | leach |
| Exemplary | 31 | Bi | with | brushing | OK | OK 54 | OK 65 | OK | OK |
| embodiment | 32 | Cu | with | brushing | OK | OK 71 | OK 73 | OK | OK |
| | 33 | Ge | with | brushing | OK | OK 50 | OK 55 | OK | OK |
| | 34 | Mn | with | brushing | OK | OK 62 | OK 51 | OK | OK |
| | 35 | Ti | with | brushing | OK | OK 54 | OK 57 | OK | OK |
| | 36 | Zn | with | brushing | OK | OK 54 | OK 53 | OK | OK |
| Control | 37 | without | without | brushing | NG | NG 2 | NG 51 | NG | NG |
| example | 38 | without | with | brushing | NG | NG 2 | NG 46 | OK | OK |

1. A multi-layer ceramic substrate comprising:
a glass ceramic;
and
an external terminal formed on at least a surface of the glass ceramic;
wherein the external terminal includes conductive materials mainly composed of at least one among Ag, Au, Pt and Pd, and includes at least one element among Bi, Cu, Ge, Mn, Ti and Zn, and inorganic oxide particles are provided on a surface of the external terminal.

2. The multi-layer ceramic substrate of claim 1, wherein the inorganic oxide particles shall include at least one among Al₂O₃, ZrO₂ and MgO as a main material.

3. The multi-layer ceramic substrate of claim 1, wherein the external terminal includes a same glass as used in the glass ceramic.

4. The multi-layer ceramic substrate of claim 1, wherein the glass ceramic is formed from a glass and a filler, where the glass shall be alkaline earth silicate series glass including 40 to 50 wt % of SiO₂, 0 to 10 wt % of B₂O₃ and 25 to 50 wt % of MO (M is at least one element among Ba, Ca and Sr), and the filler shall include at least Al₂O₃, MgO and ROa (R is an element selected at least one among La, Ce, Pr, Nd, Sm and Gd, and a is a value determined stoichiometrically according to the valence of R).

5. A process for producing a multi-layer ceramic substrate, comprising the steps of:
forming a layered-green-sheet provided with an external terminal, formed from conductive materials mainly composed of at least one among Ag, Au, Pt and Pd, and added with at least one element among Bi, Cu, Ge, Mn, Ti and Zn, formed on at least a surface of the layered-green-sheet;
layering a shrink-proof layer, which is a ceramic green sheet including an organic binder and mainly composed of a sintering resistant inorganic material, on at least a surface of the layered-green-sheet;
sintering a layered green sheet to produce a multi-layer ceramic substrate after removing the binder included in a lamination formed of the shrink-proof layer and layered green sheet; and
removing the shrink-proof layer from the multi-layer ceramic substrate,
wherein the sintering resistant inorganic material forming the shrink-proof layer is removed not fully but partially from the surface of the external terminal to use the residual as inorganic oxide particles 6.

6. The process for producing the multi-layer ceramic substrate of claim 5, wherein the sintering resistant inorganic material is added with at least one among Al₂O₃, ZrO₂ and MgO as a main material.

7. The process for producing the multi-layer ceramic substrate of claim 5, wherein the shrink-proof layer is removed by blast finishing using a media including Al₂O₃ or ZrO₂ as a main material.

8. The process for producing the multi-layer ceramic substrate of claim 7, wherein the blast finishing is to spray a slurried media.

9. The process for producing the multi-layer ceramic substrate of claim 5, wherein the shrink-proof layer formed from the sintering resistant inorganic material is added with at least one oxide compound of among Bi, Cu, Ge, Mn, Ti and Zn.

10. The multi-layer ceramic substrate of claim 2, wherein the glass ceramic is formed from a glass and a filler, where the glass shall be alkaline earth silicate series glass including 40 to 50 wt % of SiO₂, 0 to 10 wt % of B₂O₃ and 25 to 50 wt % of MO (M is at least one element among Ba, Ca and Sr), and the filler shall include at least Al₂O₃, MgO and ROa (R is an element selected at least one among La, Ce, Pr, Nd, Sm and Gd, and a is a value determined stoichiometrically according to the valence of R).

11. The multi-layer ceramic substrate of claim 3, wherein the glass ceramic is formed from a glass and a filler, where the glass shall be alkaline earth silicate series glass including 40 to 50 wt % of SiO₂, 0 to 10 wt % of B₂O₃ and 25 to 50 wt % of MO (M is at least one element among Ba, Ca and Sr), and the filler shall include at least Al₂O₃, MgO and ROa (R is an element selected at least one among La, Ce, Pr, Nd, Sm and Gd, and a is a value determined stoichiometrically according to the valence of R).

12. The process for producing the multi-layer ceramic substrate of claim 6, wherein the shrink-proof layer formed from the sintering resistant inorganic material is added with at least one oxide compound of among Bi, Cu, Ge, Mn, Ti and Zn.
